(19) United States
(12) Patent Application Publication
(10) Pub. No.: US 2016/0014882 A1
(43) Pub. Date: Jan. 14, 2016

(54) TILED DISPLAYS

(71) Applicant: FLEXENABLE LIMITED, Cambridge, Cambridgeshire (GB)

(72) Inventors: Jan Jongman, Cambridge, Cambridgeshire (GB); William Reeves, Cambridge, Cambridgeshire (GB)

(21) Appl. No.: 14/772,360

(22) PCT Filed: Feb. 28, 2014
(86) PCT No.: PCT/GB2014/050590

§ 371 Date: Sep. 2, 2015

(30) Foreign Application Priority Data
Mar. 7, 2013 (GB) 1304103.3
Jun. 20, 2013 (TW) 102121887

(51) Int. Cl. H05K 1/02; H01L 27/32; G02B 26/00; H05K 5/00; G02F 1/167

(52) U.S. Cl. CPC H05K 1/028; H05K 5/0017; G02F 1/167; G02B 26/005; H01L 27/3293

(57) ABSTRACT

The application generally relates to reflective display apparatus having a flexible display panel and driver electronics to drive the flexible display panel and methods of forming a flexible display unit for a reflective display apparatus having a flexible display panel and driver electronics to drive the flexible display panel, and more particularly to tiled displays comprising reflective, e.g., electrophoretic, display medium. One embodiment is a reflective display apparatus having a flexible display panel and driver electronics to drive the flexible display panel, the flexible display panel comprising at least first and second flexible display units, the driver electronics configured to drive said flexible display units to display respective image regions, wherein said first and second said flexible display units are adjacent and each comprise: a display layer comprising display medium; and a control layer having a backplane and a substrate to support the backplane, the backplane to control said display layer to display an image region, wherein: the driver electronics comprises a first drive electronics unit to control the backplane of said first display unit and a second drive electronics unit to control the backplane of said second display unit, said first drive electronics unit disposed on said first display unit and said second drive electronics unit disposed on said second display unit, a said drive electronics unit is mounted behind a said substrate of a said adjacent display unit to thereby substantially hide the said drive electronics unit from a user viewing a said image region displayed on the said adjacent display unit, wherein the display layer of the said adjacent display unit is in front of the said substrate, the said drive electronics unit attached to a said adjacent display unit.

### FIELD OF THE INVENTION

This invention generally relates to reflective display apparatus having a flexible display panel and driver electronics to drive the flexible display panel and methods of forming a flexible display unit for a reflective display apparatus having a flexible display panel and driver electronics to drive the flexible display panel, and more particularly to tiled displays comprising reflective, e.g., electrophoretic, display medium.

### BACKGROUND TO THE INVENTION

Difficulties are generally encountered in providing large area displays. For example, large plasma and LCD displays are expensive and for outdoor application prone to damage. Tiled displays may be present a more economically viable alternative, for example by allowing higher manufacturing yield. Such tiled displays comprise multiple display units arranged to provide a larger display that can display an image over a correspondingly large area, e.g., >2 m². LCD, rear projection and LED tiled displays are discussed below.

Tiled LCD displays, such as that shown in FIG. 1, may provide one or more of the following advantages: use of standard LCD displays; good resolution; good colour performance. However, they may suffer from one or more of the following disadvantages: difference in brightness and colour between neighbouring displays; large gap between neighbouring displays; emissive displays are difficult to read for outdoor applications. Furthermore, tiled LCD displays generally have a large gap of about 20 mm between the neighbouring displays making an image displayed across the display not continuous.

Tiled rear projection displays, such as that shown in FIG. 2, may provide one or more of the following advantages: seamless displays, i.e., very small gap between neighbouring displays; good resolution. However, they may suffer from one or more of the following disadvantages: difference in brightness and colour between neighbouring displays; additional space required to project image; emissive displays are difficult to read for outdoor applications; high power consumption and heat dissipation.

Tiled LED displays, such as that shown in FIG. 3, may provide one or more of the following advantages: modular system; seamless. However, they may suffer from one or more of the following disadvantages: low resolution , e.g., 6-8 mm pixel pitch; expensive; high power consumption; heavy.

There remains a need for a method of providing an improved tiled display. Such a display may have any one or more of the following example advantages: reduced and/or minimised gap between tiled display units, ideally to make the image display at least substantially seamless; light weight; low power consumption; flexible for allowing conformal shapes to be made; thin, e.g., <1 cm; good resolution (low or high depending on requirements); reduced driver electronics; and/or more robust, etc.. For example, a display may be less dangerous when falling on top of people if it is, e.g., a light weight and/or more robust (e.g. doesn't shatter and/or is not completely rigid so absorbs some shock).

### SUMMARY

According to a first aspect of the present invention, there is provided a reflective display apparatus having a flexible display panel and driver electronics to drive the flexible display panel, the flexible display panel comprising at least first and second flexible display units, the driver electronics configured to drive said flexible display units to display respective image regions, wherein said first and second said flexible display units are adjacent and each comprise: a display layer comprising display medium; and a control layer having a backplane and a substrate to support the backplane, the backplane to control said display layer to display an image region, wherein: the driver electronics comprises a first drive electronics unit to control the backplane of said first display unit and a second drive electronics unit to control the backplane of said second display unit, said first drive electronics unit disposed on said first display unit and said second drive electronics unit disposed on said second display unit, a said drive electronics unit is mounted behind a said substrate of a said adjacent display unit to thereby substantially hide the said drive electronics unit from a user viewing a said image region displayed on the said adjacent display unit, wherein the display layer of the said adjacent display unit is in front of the said substrate, the said drive electronics unit attached to a said adjacent display unit.

(The drive electronics unit mounted behind the substrate may further be located behind other layers attached to the back surface of the substrate in an embodiment. The electronics unit may be an outermost, back surface of the adjacent display unit, the display layer of that display unit visible from the front surface of the display unit. Preferably, the drive electronics unit is mounted behind a back side of a said adjacent display unit, the display layer of said adjacent display unit visible on the front, display side of the said display unit).

Thus, an embodiment may thus comprise a number of display units tiled—for example neighbouring in a common plane or wherein edges of units overlap—to provide a larger overall display panel. Advantageously, a substantially continuous display area may then be achieved across the entire panel, at least as it appears to the user. This may be achieved by placing the drive electronics units of displays units on the undersides of their respective display units, so that a gap between active display regions of neighbouring display units within a plane of a display layer(s) of the display units is not necessary for drive electronics or connections to such electronics.

For example, a drive electronics unit behing the back side may be considered as being under and/or behind the display unit when the display unit is viewed from viewing side of the display panel, i.e., when looking at the display panel from above and/or in front of the display medium.

Preferably, the or each such drive electronics unit behind such a display unit back side is substantially hidden from a user viewing from the front side. For example, this may be the case if the drive electronics unit is fully hidden from the user by the display unit it drives, or if the drive electronics unit is not behind the display unit it drives but is hidden behind an overlapping edge of a neighbouring display unit.

The panel may be used to display an overall image or a set of smaller images. Thus, each said image region may be an entire image or a portion of a larger, overall image.

Further preferably, the first and second display units are arranged such that substantially no gap is visible at an interface between the display layers of the adjacent display units, particularly when the display panel is viewed from a viewing side of the display panel. Such a gap may be considered to be lateral (e.g., in a plane of a display layer (s)), i.e., neglecting any vertical step in an embodiment from an upper surface of one display layer up to the upper surface of an overlapping display layer. Active regions of the display layers of the adjacent display units are preferably substantially directly opposing (even touching) at an interface between said display units, such that substantially nothing except perhaps encapsulation is disposed in a gap at the interface between the display layers.

In one option, an edge region of the first display unit has an extension beyond the display layer of the first display unit, said extension attached to said first drive electronics unit; and the second display unit overlaps said first display unit to thereby substantially hide said first drive electronics unit from a user viewing a said image region displayed on the second adjacent display unit. Thus, the second display unit may overlap the first display unit such that the first drive electronics unit is behind the second display unit (at least when the apparatus is viewed from the viewing side). Thus, a display unit may be bent to partially extend under an adjacent display unit, the thus overlapping display unit edge region hiding an edge of the bent unit when the first display unit is viewed from the viewing side. Specifically, the second display unit may overlap the first display unit such that the extension is behind the second display unit. Where drive electronics is attached to such an edge, such electronics may then be hidden from the user. Active regions of the display layers of the display units may then be immediately adjacent to allow a substantially continuous overall display surface. Preferably, the front surfaces of the neighbouring display units at an interface between them are in a substantially common plane, e.g., exactly flush, however in other embodiments there may be a vertical step due to the overlap, which is generally substantially imperceptible to a user.

There may further be provided the apparatus, wherein the second display unit overlaps said first display unit to thereby substantially hide an edge region of the display layer of the first display unit from a user viewing a said image region displayed on the second adjacent display unit. Thus, the second display unit may overlap the first display unit such that an edge region of the display layer of the first display unit is behind an edge region of the display layer of the second display unit (at least when the apparatus is viewed from the viewing side). In an embodiment, active/driven areas of the display layers of the adjacent display units may thus appear to present a substantially continuous surface to the user viewing from the viewing side (neglecting any generally imperceptible step due to overlap in a less advantageous embodiment compared to one where the front surfaces of the display units are substantially flush).

In another option, the first drive electronics unit is attached to a back surface of the first display unit (thus preferably mounted behind the substrate, e.g., mounted on a said back surface of the first display unit); and each of said first and second said display units has an edge region comprising a via through the substrate of the display unit, the via electrically coupled to the backplane of the display unit, wherein said edge regions of the first and second display units are adjacent, the display apparatus comprising: a conductive interconnection layer on the back surface of the first display unit and on the back surface of the second display unit, the interconnection layer extending between said vias, wherein the first or second drive electronics unit is coupled to said conductive interconnection layer.

Such mounting on a back side may allow the drive electronics to be hidden under/behind the display unit when the display unit is viewed from the front, i.e., when the user is looking at the display unit display medium. Similarly, the conductive layer (for example, a metallic, preferably sputtered, layer—e.g., gold) may be under/behind the display unit when the display unit is viewed from the front. Thus, an embodiment may use vias in adjacent edges of neighbouring display units to connect from a backplane to a driver electronics unit that is preferably hidden from the user viewing the front, display side of the display unit. Preferably, the drive electronics unit is direcltly mounted on (e.g., bonded to using solder or ACF) respective conductive layers.

According to a second aspect of the present invention, there is provided a reflective display apparatus having a flexible display panel and driver electronics to drive the flexible display panel, the flexible display panel comprising at least first and second flexible display units, the driver electronics configured to drive said flexible display units to display respective image regions, wherein said first and second said flexible display units are adjacent and each comprise: a display layer comprising display medium; and a control layer having a backplane and a substrate to support the backplane, the backplane to control said display layer to display an image region, wherein the display apparatus comprises: an interconnection arranged to electrically couple the first and second flexible display units such that at least one signal to drive the backplane of the first display unit is receivable from the backplane of the second display unit.

In an embodiment, the driver electronics is advantageously beyond the periphery of the display panel and/or at least the first display unit has substantially no driver electronics mounted on it. This may be achieved by providing extension(s) to extend and expose backplane electrodes, such that such electrodes of neighbouring units can be electrically interconnected, e.g., using solder or ACF. For example, display units may be effectively daisy-chained in at least one dimension. Source (control) electrodes of respective displays in a chain of two or more displays may be connected to effectively provide a single electrode across the display panel, the single electrode extending from peripheral driver electronics. Preferably, the interconnection comprises a conductive bond, e.g. ACF or solder, arranged to physically bond, advantageously by means of a substantially (including fully) rigid physical and electrical bond, the first and second display units.

There may further be provided the reflective display apparatus, wherein said interconnection is arranged to physically couple at least one electrode of said first display unit to at least one electrode of the second display unit, wherein said at least one electrode of the first display unit is electrically coupled to the backplane of said first display unit and said at least one electrode of the second display unit is electrically coupled to the backplane of said second display unit. Thus, for example, the backplanes of the first and second display units may have at least one source or control electrode in common. Depending on drive capability, e.g., output impedance and/or maximum current output, of the driver electronics, which is preferably located at an outer edge of the overall display panel, such a common electrode may extend across a two or a higher number of tiled display units, e.g., 5 or 10. Driver electronics may be provided along one edge of the panel to drive common source electrodes and/or along another edge of the panel to drive common control electrodes. Similarly, other tracks/electrodes such as power and voltage reference lines may extend from such driver electronics across the series of display units.

There may further be provided the reflective display apparatus, wherein: the control layer of the first display unit has an extension beyond the display layer of the first display unit, the extension comprising at least one electrode electrically coupled to the backplane of the first display unit; and said interconnection electrically couples the at least one electrode to the backplane of the second display unit such that the at least one said signal is receivable by the at least one electrode. Such an extension may allow the electrode(s) to be exposed and thus coupled, e.g., using solder and/or ACF, to receive the signal from the edge electronics.

There may further be provided the reflective display apparatus, wherein the backplane of each of said first and second flexible display units comprises a plurality of transistors, control electrodes and source electrodes, wherein: each said transistor of a said flexible display unit is configured to receive a control signal from a said control electrode and a source signal from a said source electrode and configured to drive a region of the display medium of the flexible display unit by controllably passing said received source signal, said controllable passing under control of said received control signal; and the at least one electrode of said first display unit comprises a said control electrode and the at least one electrode of said second display unit comprises a said control electrode, the interconnection arranged to electrically couple said control electrodes.

There may further be provided the reflective display apparatus, wherein the backplane of each of said first and second flexible display units comprises a plurality of transistors, control electrodes and source electrodes, wherein: each said transistor of a said flexible display unit is configured to receive a control signal from a said control electrode and a source signal from a said source electrode and configured to drive a region of the display medium of the flexible display unit by controllably passing said received source signal, said controllable passing under control of said received control signal; and the at least one electrode of said first display unit comprises a said source electrode and the at least one electrode of said second display unit comprises a source electrode, the interconnection arranged to electrically couple said sources electrodes.

Preferably, the driver electronics comprises a driver electronics unit located beyond an edge, for example at the periphery of and/or in a margin/peripheral frame of, the display panel. Additionally or alternatively however the driver electronics may be provided under any part of the flexible display panel provided that it does not obstruct viewing of desired active areas of the display layers of the tiled units.

Nevertheless, it is generally preferred that neither of the first and second display units has driver electronics mounted on them and most preferably no driver elecronics is mounted on any of the display units of a tiled display having more than first and second display units (except to the extent that such mounting on display units at the edge of the overall panel helps to support driver electronics located beyond the panel).

In one option, the control layer of the second display unit has an extension beyond the display layer of the second display unit, the extension comprising at least one electrode electrically coupled to the backplane of the second display unit; the interconnection couples the extensions of the first and second display units at an interface between said adjacent display units, and: at least one said extension of a said display unit has a curvature toward a non-viewing side of the display unit (a side from where a user would be looking at the non-display back surface of the unit, an image region displayed on the display layer being visible on the front surface, said curvature to reduce a gap between the display layers of the adjacent display units at said interface. Preferably, the gap is eliminated by such reduction bringing the periphery of neighbouring active display layer areas substantially into contact, or at least the gap is reduced to a width of less than about 1 mm. Thus, neighbouring display units may by physically and/or electrically connected by bonding adjacent respective extensions of the units, the extensions bent back so that bonded surfaces of the extensions oppose each other and the active (driven) display layer areas of the units are brought closer together than, if the extensions were not bent back, e.g., out of a common plane of the display layers.

There may be further provided the option wherein the curvature of at least one of the coupled extensions is about 90 degrees such that the extensions extend substantially perpendicular to the display layer of at least one said adjacent display unit, e.g., the extensions are bent at right angles to their respective display layers and away from the viewing side(s) of the display units or panel.

In view of the above, the option may advantageously allow a reflective display apparatus, wherein the curvature of at least one of said extensions is such that the display layers of the adjacent display units are directly opposing at the interface between the units. Thus, there may be substantially nothing except perhaps encapsulation (preferably transparent and/or for improved ruggedness and/or moisture protection) in a gap at the interface between the units—preferably the active display areas of the units are in substantially direct contact.

There may further be provided the reflective display apparatus, wherein the at least one said extension comprises a track of a said electrode, said curvature such that said electrode track is curved, the extension further comprising a conducting polymer, preferably ductile, such as Pedot over the electrode track. Such a covering layer over such a track(s) (preferably deposited directly onto the surface of, i.e., in contact with, the track(s)) may reduce cracking of and/or likelihood of open circuit along, the track—the likelihood of such a break in the track may otherwise be increased by strain due to the curvature.

In another option, the second display unit comprises a via through the substrate of the second display unit; and the second display unit overlaps the extension of said first display unit such that said via is located over the extension of the first said adjacent display unit, wherein said interconnection comprises said via. Thus, an embodiment may hide the extension of one display unit behind a neighbouring display unit, at least from the perspective of the user viewing an image on the display panel.

Preferably, the apparatus comprises anisotropic conductive film (ACF) disposed to electrically couple the via to the second display unit, e.g., to couple the via of the first unit to the backplane of the first unit. Advantageously, the via enables electrical conduction between the backplanes of the units and/or coupling of power and/or ground rails between the units.

Further preferably, the substrate and an active area of the display layer of the second display unit extend over the extension of the first display unit. In this way, the active areas of neighbouring units may positioned substantially directly adjacent each other (neglecting—in a less advantageous embodiment where the display units are not substantially flush—any step due to the overlap of the units, this being in embodiments substantially imperceptible to the user viewing an image(s) on the units).

There may further be provided the apparatus, wherein the extension of said first display unit comprises a track of a the electrode and a conducting polymer such as Pedot over the electrode track. Similarly as above, such a layer of polymer preferably deposited directly onto the track(s) reduces the likelihood of a break in conductivity of the track, for example due to flexing of the apparatus during use.

Preferably, at least the substrate comprising the via is a plastic substrate. The via may then be formed by laser ablation of the substrate. This may be advantageous for example compared to a display apparatus having glass substrate that is liable to shatter or crack during formation of a via or due to dislocations subsequently forming at stress points at the via.

In any embodiment as described above, preferably a gap between said display layers of said adjacent first and second display units has a shortest width less than about 1 mm.

Preferably, at least one of said adjacent display units comprises a planarisation layer disposed on the backplane of the display unit, said planarisation layer for reducing cracking of electrical tracks of the backplane.

Preferably, the substrate of at least of the adjacent display unit comprise PEN (e.g., 50 um) or PET (e.g., 50 or 125 um). In this regard, however, it is noted that the thinner substrate is preferred.

Preferably, the display medium comprises electrophoretic, electrowetting, electrofluidic display medium. Alternatively, the display may be an OLED display.

Further optionally, the driver electronics is configured to drive said flexible display units to display an image comprising said respective image regions.

Advantageously, there may further be provided the reflective display apparatus of any one of the above aspects and optional embodiments, wherein electrical routing (e.g., tracks, electrodes) between a said backplane (e.g., preferably circuitry for driving an active region of the display layer) of a first said display unit and a drive electronics unit configured to drive said backplane is arranged behind an adjacent said display unit to thereby substantially hide said drive electronics unit from a user viewing an image region displayed on the first display unit.

According to another aspect of the present invention, there is provided a method of forming a flexible display unit for a reflective display apparatus having a flexible display panel and driver electronics to drive the flexible display panel, the flexible display panel comprising at least first and second said flexible display units, the driver electronics configured to drive said flexible display units to display respective image regions, wherein said first and second said flexible display units are adjacent, the display unit having a display layer comprising display medium and having a control layer having a backplane and a substrate to support the backplane, the backplane to control said display layer to display an image region, the method comprising: processing a process element comprising a said substrate, a said display layer and a said backplane, said element adhered to a substantially rigid plate during said processing, said plate for supporting said unit and reducing deformity of the display layer during said processing; substantially inhibiting said adherence after said processing; separating said unit and said plate when said adherence is substantially inhibited; and depositing, e.g., evaporating or sputtering, an electrically conductive layer on a back surface of said unit, wherein the display layer is visible through a front, display surface of the unit, said depositing when the back surface has has been exposed by said separating. (The display layer may be on a front side of the unit, said depositing when the back side has has been exposed by said separating). Where the adherence is provided by a temperature-sensitive adhesive, reducing or stopping the adherence may be achieved by changing, e.g., lowering the temperature (or raising if the adherence is less at higher temperature). Alternatively, the adhesive may be UV release adhesive. Regardless, the method may thus comprise turning the unit over to deposit the electrically conductive layer on the back side.

The method may further comprise mounting on the conductive layer a drive electronics unit of the driver electronics, the mounting preferably comprising using solder or ACF to bond the drive electronics unit to the conductive layer.

The method may further comprise bonding the conductive layer to an electrode of another said display unit, preferably using ACF or solder. Thus, the conductive layer may be be part of a signal and/or power conduction path between neightbouring display units, e.g., between their backplanes. Additionally or alternatively, bonding may provide an interconnection that electrically couples the flexible display unit to the another display unit such that at least one signal to drive the backplane of the flexible display unit is receivable from the backplane of the another display unit—preferably the interconnection comprises a conductive bond, e.g. ACF or solder, arranged to physically bond, e.g., e.g. rigid physical and electrical bond, the first display unit to the second display unit.

According to a further aspect of the present invention, there is provided a method of forming a flexible display unit for a reflective display apparatus having a flexible display panel and driver electronics to drive the flexible display panel, the flexible display panel comprising at least first and second said flexible display units, the driver electronics configured to drive said flexible display units to display respective image regions, wherein said first and second said flexible display units are adjacent, the display unit having a display layer comprising display medium and having a control layer having a backplane and a substrate to support the backplane, the backplane to control said display layer to display an image region, the method comprising: forming a said substrate for supporting a said backplane to drive a said display layer visible through a front, display surface of a said flexible display unit; ablating said substrate to form a hole through said substrate; and coating an internal surface of said hole to form a via for electrical conduction from the backplane to a back side of the substrate when the backplane is on a front, display surface of the substrate. Advantageously, the substrate comprises plastic, glass and/or aluminium foil. Preferably, the ablating is laser ablation and/or the coating is performed by sputtering. Additionally or alternatively, the coating may involve partially or fully filling the via with a conductive material, e.g., metal.

Such a method may further comprise mounting a drive electronics on a back surface of the display unit by bonding the via at the back surf aceside to a drive electronics unit, preferably using solder or ACF. Additionally or alternatively, such a method may further comprise bonding the via at the back surface to a drive electronics unit to an electrode of another display unit, preferably using solder or ACF. Such bonding may provide an interconnection that electrically couples the flexible display unit to the another display unit such that at least one signal to drive the backplane of the flexible display unit is receivable from the backplane of the another display unit. The interconnection may comprise a conductive bond, e.g. ACF or solder, arranged to physically bond the first display unit to the second display unit.

Preferred embodiments are defined in the appended dependent claims.

Any one or more of the above aspects and/or any one or more of the above optional features of the preferred embodiments may be combined, in any permutation.

Further aspects may comprise methods (apparatus) corresponding to the above apparatus (method) aspects.

### BRIEF DESCRIPTION OF THE DRAWINGS

For a better understanding of the invention and to show how the same may be carried into effect, reference will now be made, by way of example, to the accompanying drawings, in which:

FIG. 1 shows a tiled LCD display;

FIG. 2 shows a tiled rear projection display;

FIG. 3 shows tiled LED displays in the form of “fashion pillars”;

FIG. 4 shows a prototype embodiment using the configuration of option 3, the prototype being in the form of a 3×3 tiled reflective display;

FIG. 5 illustrates a plan view of an embodiment of the first option;

FIG. 6 illustrates cross-sectional and plan views of a display unit of the embodiment of the first option;

FIG. 7 shows a cross-sectional view of the embodiment of the first option (driver electronics not shown);

FIG. 8 shows the embodiment of the first option in a product configuration;

FIG. 9a shows a schematic lay-out of an embodiment of the second option (driver electronics not shown);

FIG. 9b shows cross-sectional and plan views of a display unit of the embodiment of the second option;

FIG. 10 shows such an embodiment of the second option having driver electronics on respective display units;

FIGS. 11a and 11b illustrate cross-sectional and partial plan views of an embodiment of the third option, respectively; FIG. 11c shows side, front and back views of a display unit (tile) of such an embodiment; FIG. 11d shows side, front and back views of a tiled display panel of such an embodiment;

FIG. 12a illustrates display encapsulation for an embodiment of the third option; FIG. 12b shows encapsulation options for an an embodiment of the third option.

FIG. 13a shows a cross-sectional structure of a display unit applicable to any embodiment of any option discussed herein, and FIG. 13b shows an alternative such cross-sectional structure;

FIG. 14 shows a block diagram of a system comprising an embodiment of a display of any option discussed herein;

FIG. 15 shows a detailed vertical cross-section view through a display unit of any embodiment of any option discussed herein;

FIG. 16a shows a front window for the display unit of FIG. 15, incorporating a touch-sensor;

FIG. 16b shows a colour filter array for the display unit at FIG. 15;

FIG. 16c shows a display media layer for the device at FIG. 15;

FIG. 16d shows a substrate/backplane layer for the device at FIG. 15 mounting display interface electronics;

FIG. 16e shows a front side of a flexible PCB for the device at FIG. 15;

FIG. 16f shows a rear face of the flexible PCB for the device at FIG. 15;

FIG. 16g shows a view of the rear of the device at FIG. 15 when the back cover is not present;

FIG. 16h0 shows a rear view of the device at FIG. 15;

FIG. 16i shows an edge profile of the device at FIG. 15;

FIG. 17 shows a process flow for an embodiment comprising a via;

FIG. 18 shows an example circuit portion of a backplane, the portion for driving a pixel 2 of a display and comprising a transistor 31 driven by source and control electrodes to control light emission from the pixel; and

FIGS. 19a to 19c, which are taken from WO2004/070466, show an active matrix pixel where the display media is voltage controlled, such as for liquid crystal or electronic paper.

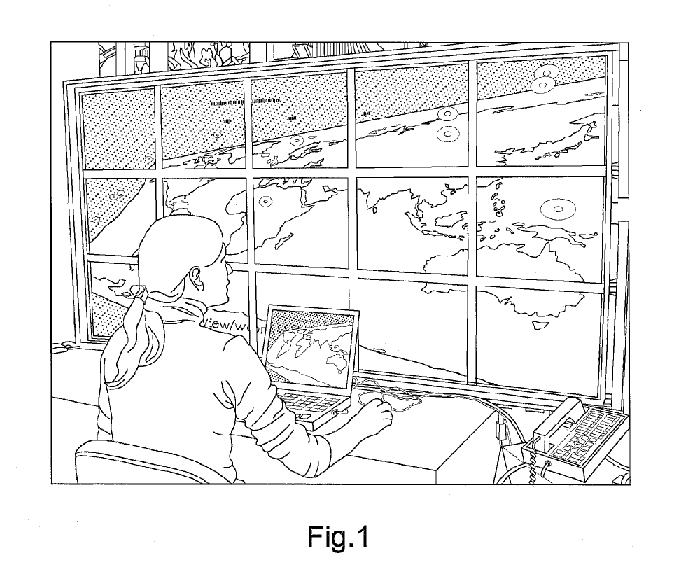

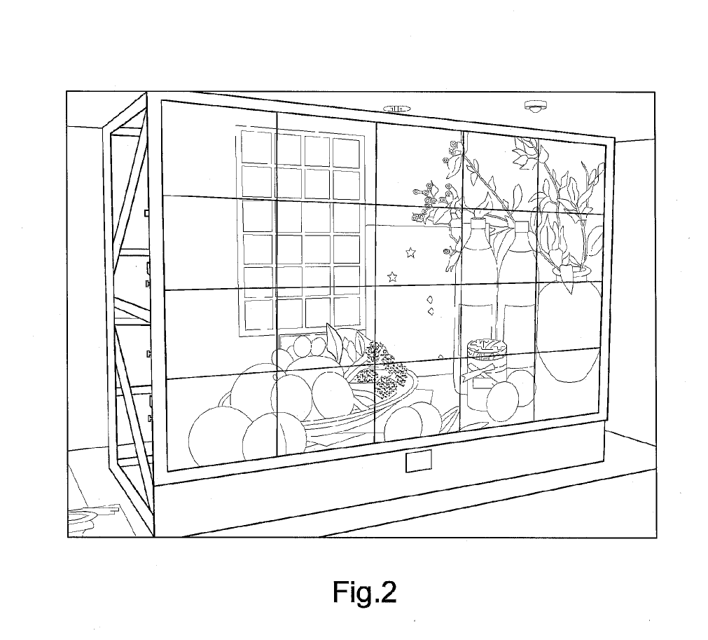

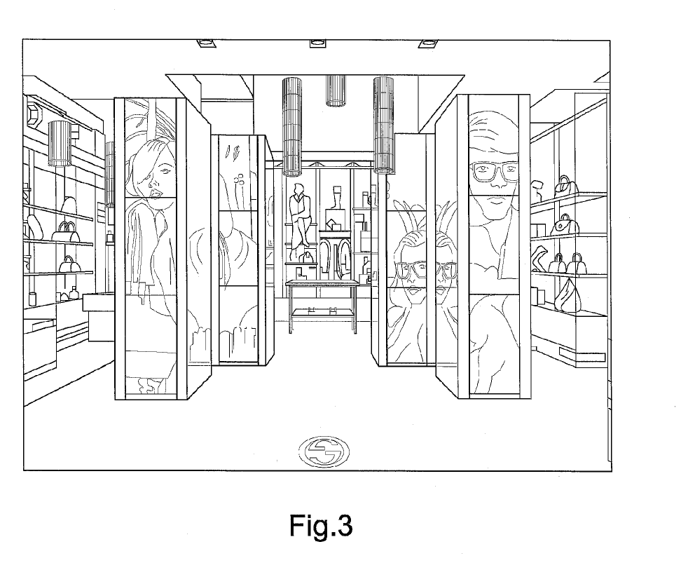

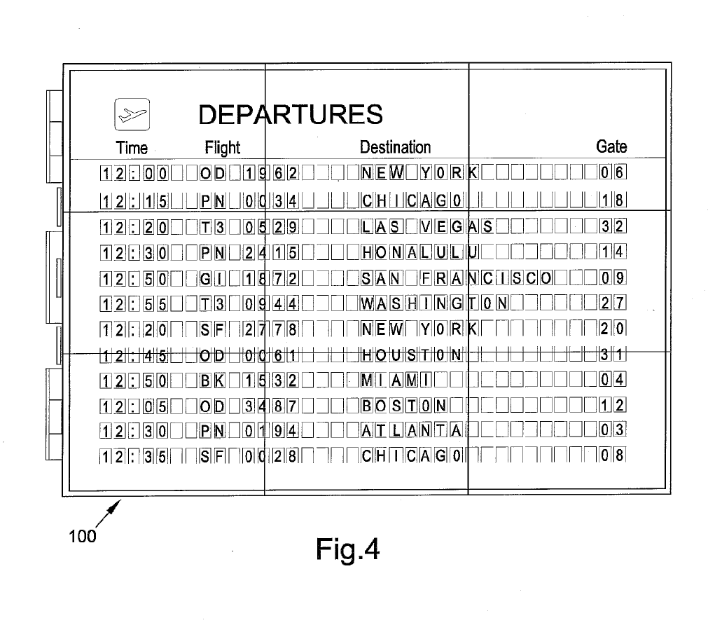

### DETAILED DESCRIPTION OF PREFERRED EMBODIMENTS

Embodiments generally relate to tiled displays using reflective displays, e.g., tiled e-paper displays. Advantageously, some embodiments may have a gap of less than 1 mm between neighbouring displays of the tiled display. Thus, an image may be displayed substantially continuously across the full display. Additionally or alternatively, an advantage may be to connect source and control electrodes (tracks) such as source and gate lines, of the multiple display units together to avoid or reduce any need to connect driver electronics to each individual display unit.

By using a reflective display medium, an embodiment may be battery operated and therefore can be stand alone, which is of clear advantage for remote locations. Such medium may also allow the display to be readable in daylight. Furthermore, by providing such a medium with a flexible backplane, an embodiment may be more resilient against vandalism.

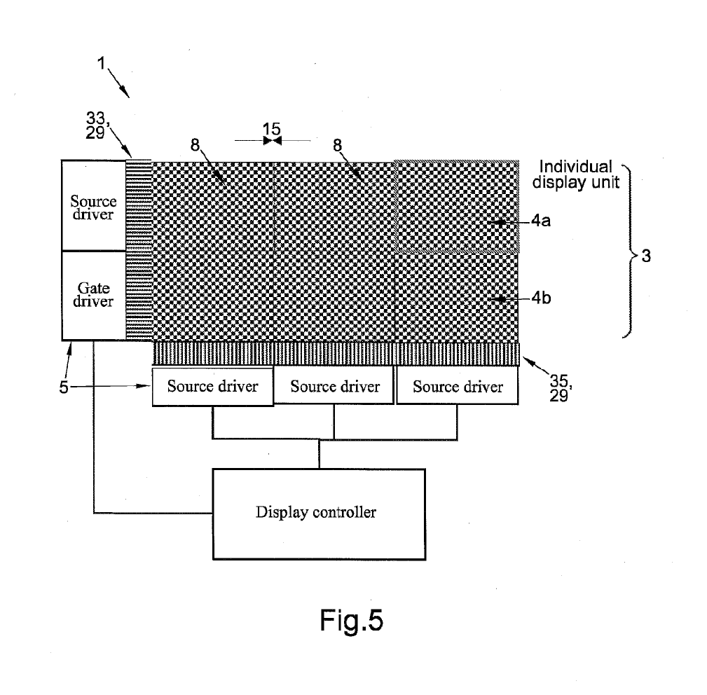

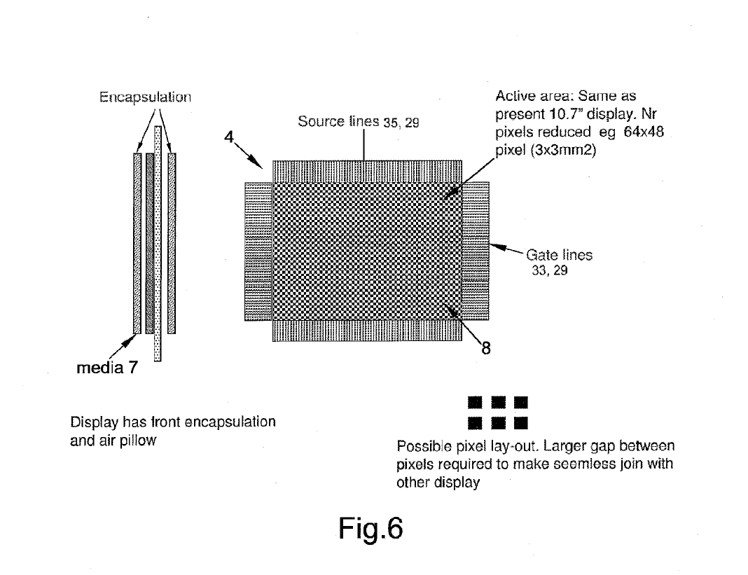

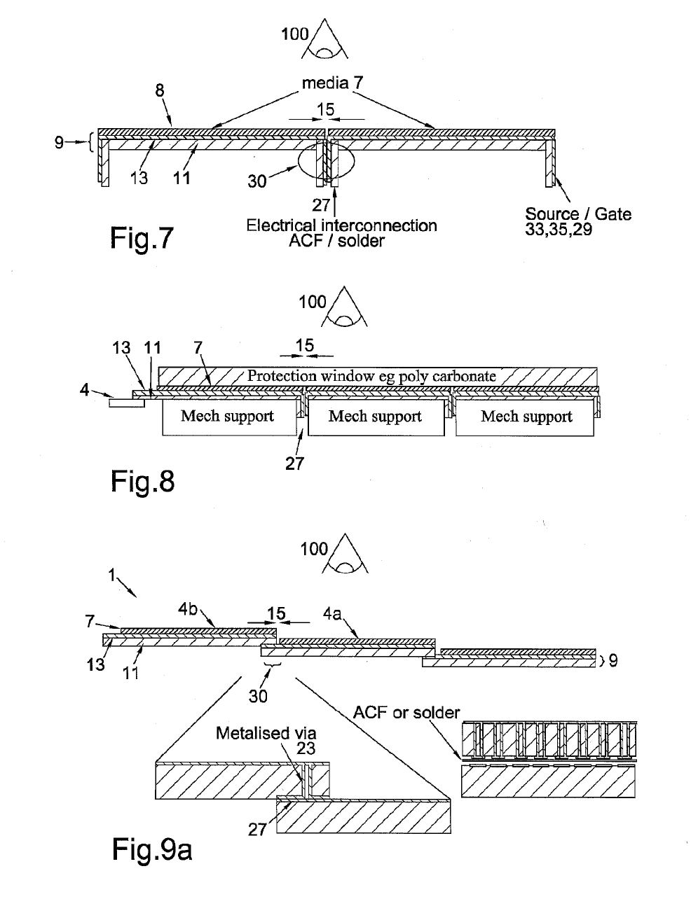

According to a first option, the display units, otherwise referred to as panels, are connected to each other by contacting bent display edges to each other. For a bonding process to bond the units, ACF or solder may be used depending for example on the bond pitch. Thus, in an embodiment of the first option, the display units are tiled together by bending the substrate 90 degrees backwards, for example as shown in FIG. 7. In such an embodiment the driver electronics are preferably located at the edge of the display, as shown in FIG. 5, each display unit preferably being configured as shown in FIG. 6. With further regard to FIG. 6 or 7, it is noted that the substrate bend radius is preferably minimised to get the panels close together. Furthermore, it may be desirable to take into account potential cracking of tracks. Further still, it is noted that alignment of the panels may be less difficult if a low track resolution is used, e.g., about 1-3 mm. In such an embodiment, as shown in FIG. 8, mechanical supports may be provided respectively for each panel and a protection window may be provided across the viewing sides of the multiple panels.

An advantage of such an embodiment is that driver electronics may be located only at the edge of the tiled display. For a display comprising X by Y units, the electronics cost may then scale as X+Y and not X*Y (i.e. product of X and Y). Additionally or alternatively, advantage(s) of the first option may include, e.g., flexible design size, and/or tracks remaining on the same side and therefore no additional process required. Preferably, PEN (e.g., 50 um) or PET (e.g., 50 or 125 um)and/or a planarisation layer is/are used to prevent or reduce cracking of the tracks, for example when an embodiment has a thin substrate. Additionally or alternatively to prevent or reduce cracking of the tracks, a conducting polymer such as Pedt (Pedot, a conducting polymer: poly(3,4-ethylenedioxythiophene)poly(styrenesulfonate)) may be deposited on the bend area in an embodiment.

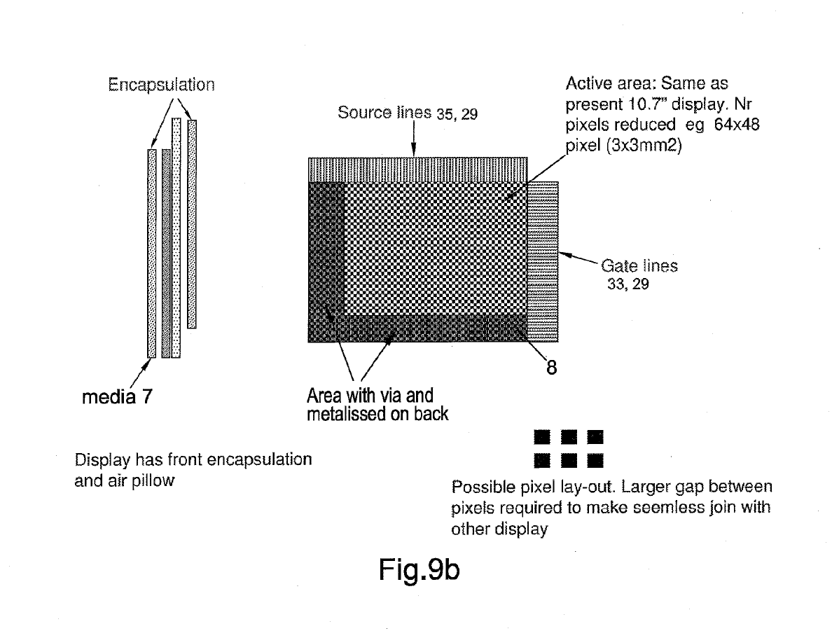

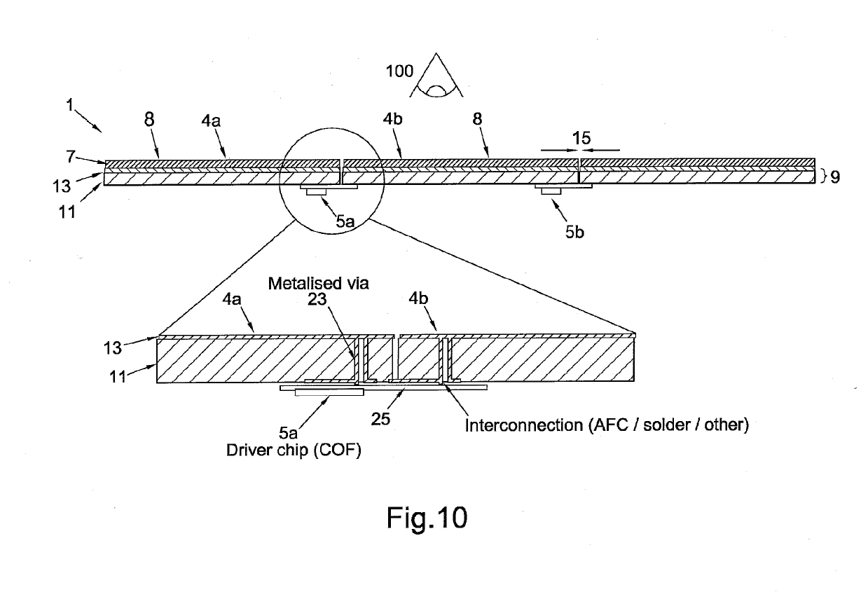

According to a second option, via(s) are formed through the substrate allowing the panel to be bonded on the back side. This is possible by using for example plastic substrates in which vias can be made. A schematic lay-out of an embodiment of the second option is shown in FIG. 9a, preferably cross-sectional and plan views being shown in FIG. 9b. The second option may allow for driver electronics to be placed at the display edge as discussed above in relation to the first option. However, where the driver electronics are connected to each individual display in an embodiment of the second option, this may allow for a more modular tiled concept. An embodiment having driver electronics on respective display units is shown in FIG. 10.

Similarly as for the first option, an advantage of an embodiment of the second option is that driver electronics may be located only at the edge of the tiled display. For a display comprising X by Y units, the electronics cost may then scale as X+Y and not X*Y (i.e. product of X and Y). Additionally or alternatively, advantage(s) of the first option may include, e.g., flexible design size, and/or tracks remaining on the same side and therefore no additional process required. Preferably, PEN (e.g., 50 um) or PET (e.g., 50 or 125 um) and/or a planarisation layer is/are used to prevent or reduce cracking of the tracks, for example when an embodiment has a thin substrate. Additionally or alternatively to prevent or reduce cracking of the tracks, Pedt may be deposited on the bend area in an embodiment.

In view of the above, FIGS. 9 and 10 show two methods to create tiled displays with vias. In one case the displays are stacked on top of each other, in the second solution the displays are in place and the interconnection between the displays is done with a 3^{rd} conductor.

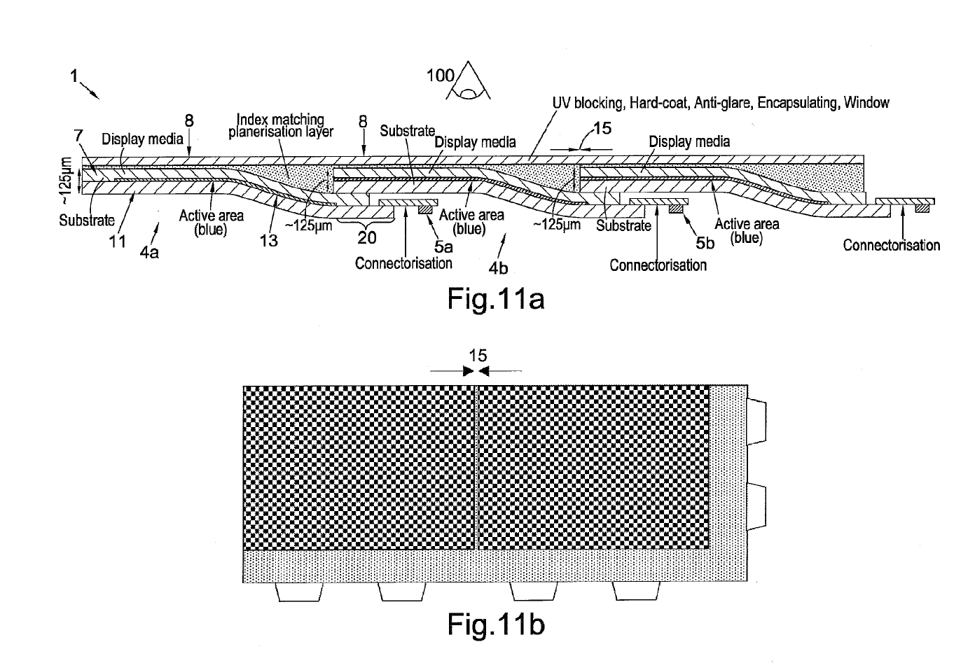

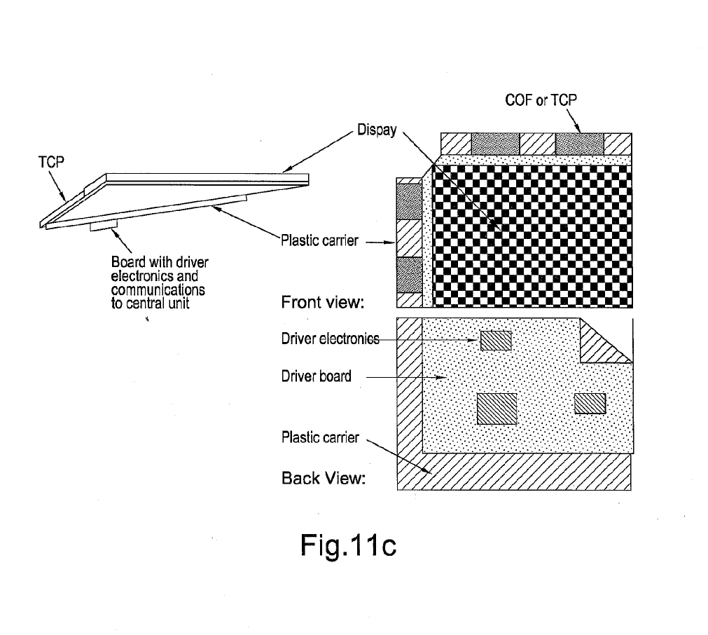

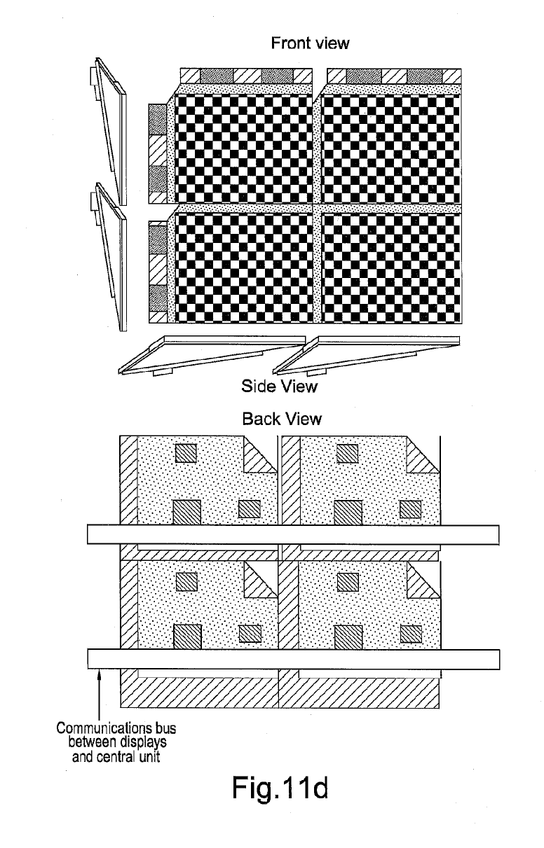

According to a third option, overlay between neighbouring units may be used for a tiled display, preferably such that the top surfaces of neighbouring display units are in a substantially common plane, e..g, exactly flush. Preferably this is achieved my bending only edge region(s) of a display unit(s), the edge region preferably not comprising display medium. A casing may be used to provide an substantially continuous, e.g., smooth, surface extending under or over neighbouring display units—thus any step due to the overlay on the underside of the neighbouring substrates may be concealed. A cross-sectional and partial plan views of an embodiment of the third option are illustrated in FIGS. 11a and 11b, respectively. According to the third option, currently available 10.7″ displays are cut to thus provide two edges of the display switching up to the edge within a tiled display, for example as shown in FIG. 11a, the tiling of such units being further shown in FIG. 11b. Advantageously, existing displays may be used, with tracking preferably stopped just before the cut to avoid shorts. The media may be laminated after the cutting procedure. The use of thinner display may reduce any step in thickness associated with the display being laid on top of each other.

(FIG. 11a is labelled to indicate: 3 sets of substrate-active area-display media (each such set having thickness of about 125 um), an uppermost layer which is preferably a UV-blocking, hard-coat, anti-glare and/or anti-glare window, an index-matchin planarisation layer between the display media and window, and connectorisation from a substrate extension of each set, the connectorisation to an electronics unit). The active area may be a backplane region to control a region of the display media, such a drivable display media region termed active.

FIG. 11c shows side, front and back views of part of a display unit (tile), the back view showing the underside of the tile. As discussed above, each module contains one display, driver electronics to drive the display and to talk to a central unit. Each unit has its own encapsulation. Note that the display is bent backwards over the plastic carrier. This feature is enabled by the use of flexible displays. The tiling concept is illustrated by FIG. 11d that shows side, front and back views of a tiled display panel. In this embodiment, there is overlap in two directions. Since the edge of the display with driver electroncis is bent backwards, the gap been the displays can advantageously be minimised.

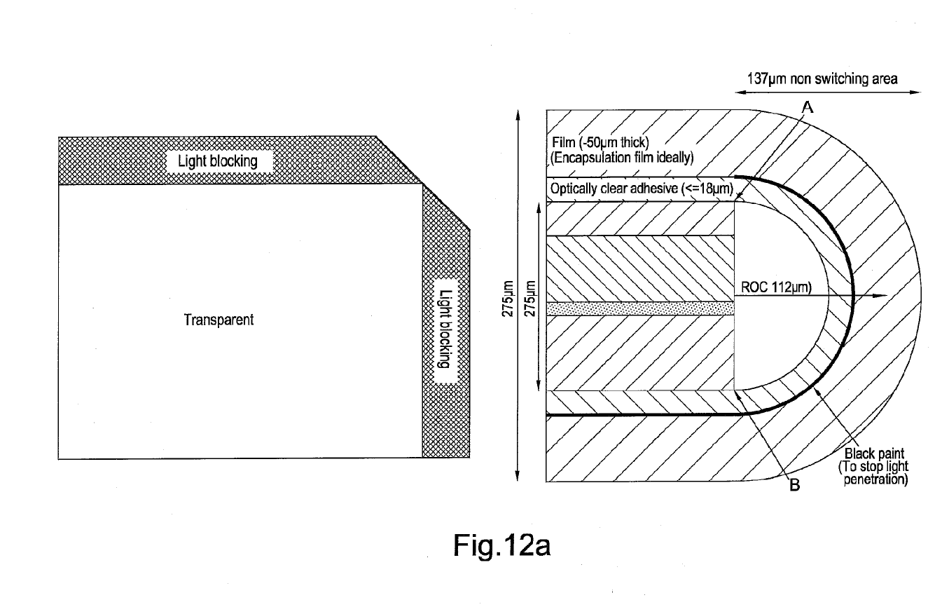

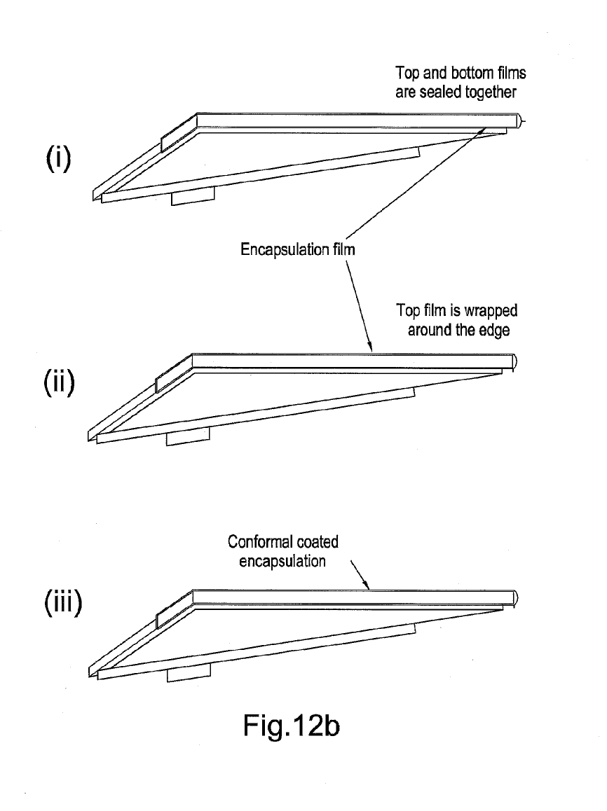

An encapsulation may be provided to protect the edge of the media for an embodiment of the third option, for example as shown in FIG. 11a wherein the gap is filled in with adhesive. A more specific embodiment of display encapsulation for the third option is shown in FIG. 12, wherein the encapsulation film is wrapped around the edge of the display. This may lead to a slightly larger gap between neighbouring displays but will results in a good edge seal.

FIG. 12b shows additional and/or alternative encapsulation options (i)-(iii) for an embodiment of the third option. In (i), top and bottom encapsulation films are sealed together. The films are transparent. The seal might be visible in display. In (ii), a top encapsulation film is wrapped around the dispaly. This may create a particularly thin seal and therefore provided good optical performance. In (iii), a coating is conformally deposited over the display, for example by spray coating, atomic layer deposition, molecular vapor deposition, sputter coating, etc.. This may similarly create a particularly thin seal.

Thus, in view of the above, encapulation may be provided individually for each tiled display unit, and/or for the whole display panel.

Embodiment representable by FIGS. 5-12b may have any one or more components for example according to the following labels:

1—reflective display apparatus

2—pixel

3—flexible display panel

4—display unit (first 4a; second 4b)

5—driver electronics unit (first 5a; second 5b)

7—display layer or medium

8—image region

9—control layer

11—substrate

13—backplane

15—gap

20—extension

23—via

25—conductive interconnection layer

27—interconnection

29—electrode(s)

30—extension

31—transistor

33—control electrode(s)

35—source electrode(s)

100—user

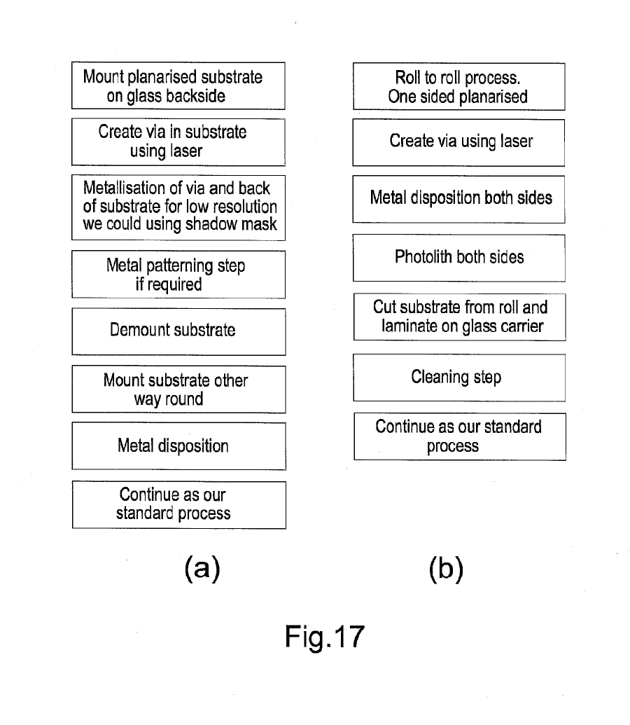

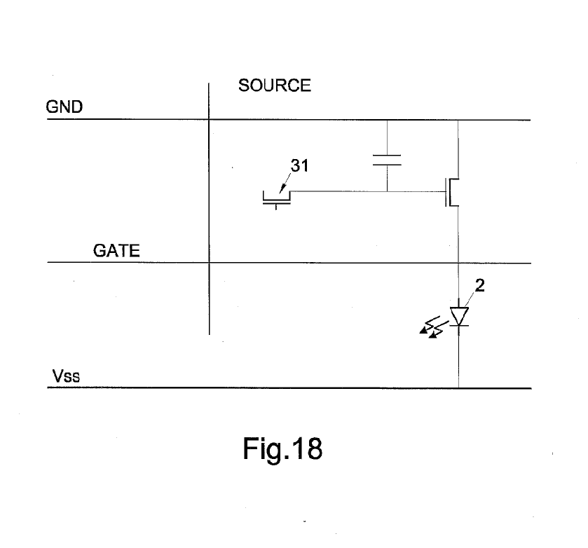

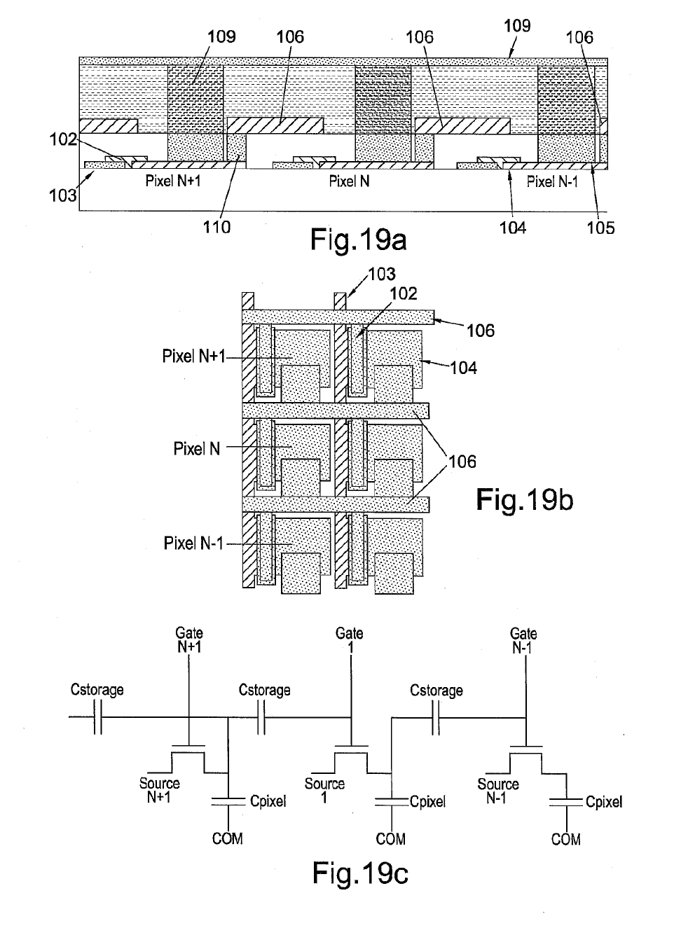

FIG. 17(a) and (b) show alternative process flows for an embodiment comprising a via, for example as shown in FIGS. 9a and 10. Consistent with for example FIG. 17(a) indicating to mount the substrate the ‘other way round’, the subtrate may be turned over such that a back surface to deposit metal on is provided on the top surface. Preferably after the via is formed, the substrate is turned over again to allow the a structure comprising the backplane and display layer to be built up on the front surface. This turning process may allow formation of a via to subsequently provide an electrical connection from a backplane near the front surface of a display unit, to an electrical bond on the back side, for example a conductive bond to a driver electronics unit, to electrode tracks of a neighbouring display unit and/or to an evaporate or sputtered metallic interconnection layer. Previously, such a turning process has not generally been provided for in a conventional production line for creating a flexible or non-flexible display.

Selected embodiments and/or options above provide a solution to tiling problems, these solutions feasible due to either or both of the following two reasons: (a) flexibility of our displays for example as applied for options 1 and 3—this flexibility may allow for a small bend radius of the display bending the border (the material outside the active area) backwards; and (b) the ability to make vias through plastic substrates may allow the additional tracking which is otherwise placed on the area outside the active area to be placed below the active area on the other side of the substrate—this may allow reducing the border width.

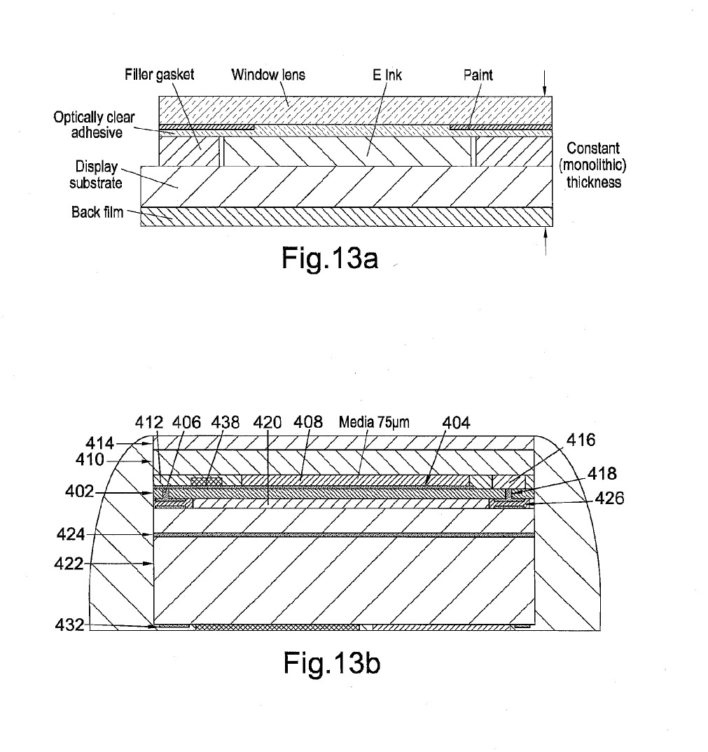

FIGS. 13 to 16 illustrate fabrication structures and techniques applicable in any combination for the construction of a display unit of an embodiment of any of the options as described and/or illustrated herein. In this regard, FIGS. 13a and 13b show alternative cross-sectional structures that may be comprised within a display unit of an embodiment. Specifically, for example, FIG. 13b shows a vertical cross-sectional view through a display unit. In this example, electronic components for the unit are located along an edge of the unit on a flexible PCB; however they may additionally or alternatively be located on the rear side of the display unit, and/or at the edge of the display comprising such display units. A display medium 408 is attached to substrate 402, for example by adhesive.

In more detail, the structure comprises a substrate 402, typically a plastic such as PET (polyethyleneterephthalate) or pen(polyethelenemaphthalene) on which is fabricated a thin layer of organic active matrix pixel circuitry. The circuitry may comprise an array of organic (or inorganic) thin film transistors for example as previously described in our WO01/47045, WO2004/070466, WO01/47043, WO2006/059162, WO2006/056808, WO2006/061658, WO2006/106365 and WO2007/029028. Broadly speaking in embodiments the backplane is fabricated using solution based techniques patterned by, for example, direct-right printing, laser ablation or photolithography to fabricate the thin film transistors. In embodiments the active devices have a thickness of order 5-10 μm. In embodiments this layer has a thickness of order 50 μm and has integrated encapsulation. This substrate/backplane layer bears row and column data lines and address conductive tracks, connected to the rear of substrate 402 by vias. We here refer to front as being towards the display surface of the screen and rear as being towards the rear of the screen.

A display medium 408 is attached to substrate 402, for example by adhesive. In preferred embodiments the display medium is a reflective display medium (which facilitates daylight reading), for example an electrophoretic, electrofluidic or OLED display medium. Where an electrophoretic display medium is employed a colour display may be provided by providing a colour filter array 410 over the display medium; optionally this may also perform an encapsulation function. Additionally or alternatively a moisture barrier may be provided over the display, for example comprising polyethylene and/or Aclar™ (a fluropolymer, polychlorotrifluoroethylene-PCTFE). In some embodiments the thickness of the display medium is of order 75 μm and that of the encapsulation/colour filter array of order 120 μm.

Where an electrofluidic display is employed, for example of the type available from Gamma Dynamics, Inc. Ohio USA, the colour filter array may be omitted. The use of an electrofluidic display facilitates improved brightness/contrast as well as near video display update rates and high resolution, in embodiments of order 225 pixels per inch.

In embodiments whichever display medium is employed, an edge seal is provided to seal the edge of display medium to the edge of the display screen.

As described above, the display medium of an embodiment is most preferably a reflective display medium (which facilitates daylight reading), in particular an electronic paper display medium, for example an electrophoretic display medium or an electrofluidic display medium. In alternative arrangements, the display unit may have an emissive, e.g., LED, or transmissive, e.g., LCD, screen.

A front window 414 may be provided, for example comprising a thin layer of PMMA (polymethylmethacrylate). Where the screen is to be touch sensitive, this layer may also include conductive row and column lines for the touch circuitry. The touch sensing circuitry may be operable by finger and/or a stylus. A connection to the touch sensing layer may be made by a Z-axis conductive pad 416 which connects to the touch electrodes in window 414 through CFA/encapsulation layer 410 (for example by vias, not shown) and vias 418 through substrate 402 bring the touch array connections to contact pads on the rear of substrate 402.

An adhesive layer 420 may connect the substrate 402 to a flexible PCB 422 (which may incorporate circuitry 424 for an inductive stylus sensor. Connections between the contact pads on the rear of substrate 402 and the flexible PCB employ an anisotropic conductive film (ACF) 426. The illustrated structure facilitates the omission of a separate moisture barrier under substrate 402, although such a barrier may be incorporated if desired.

A flexible PCB may carry electronic components, for example surface mounted components, and a thin film flexible polymer battery. The flexible PCB also may bear at least part of a conductive loop 432, for example around the border of the display unit or display, for inductive charging of battery 430. A storage device may also be carried on the flexible PCB. A thin back cover 434 may be used to provide a protective layer as described above, which may protect against impact or be waterproof.

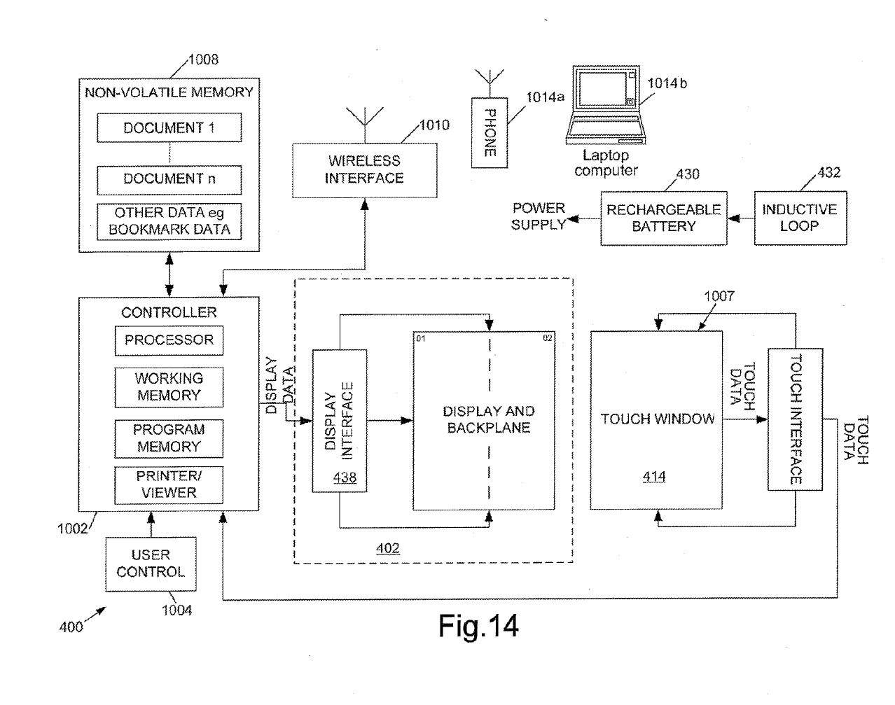

Regarding the operation of an embodiment of any of the options, FIG. 14 shows a block diagram of example electronics of a display apparatus 400. The display apparatus 400 preferably comprises display panels (display units—D1 and D2 each comprising a display layer and backplane) and a controller 1002 which includes a processor, for example an ARMTM device, working memory and program memory coupled to one or more display interface integrated circuits 438 for driving the pixel arrays of the panels—preferably by means of one such circuit per respective display unit. The interface circuit(s) may be provided beyond the display units or respective such drive circuits may be mounted underneath their respective display units. One or more touch interface integrated circuits 1006 may optionally be provided to interface with the touch electrodes on front window(s) 414 to provide touch data to controller 1002. The controller may also include a motion sensor which is capable of detecting when the display is rotated, as described above.

The display may comprise a rechargeable battery 430 and/or inductive loop 432, and/or may be powered via a USB connection. Similarly as for FIG. 14, an inductive loop 432 may be used to charge a rechargeable battery 430 which has associated circuitry for providing a regulated power supply to the system.

The program memory in embodiments stores processor control code to implement functions including an operating system, various types of wireless and wired interface, document retrieval, storage, annotation (via the touch interface) and export from the display. The stored code also includes code 1003 to implement a document viewer/‘printerless printing’ function, for example interfacing with corresponding driver code on a ‘host’ device.

The controller 1002 interfaces with non-volatile memory, for example Flash memory, for storing one or more documents for display and, optionally, other data such as user bookmark locations and the like. Optionally a mechanical user control 1004 may also be provided.

A wireless interface 1010, for example a Bluetooth™ or WiFi interface may be provided for interfacing with, e.g., a mobile electronic device. For example, the wireless interface can be used by the display to receive image data from a mobile electronic device and transmit touch data back to the mobile device. The wireless interface 1010 may comprise a Bluetooth™ RF chip and antenna.

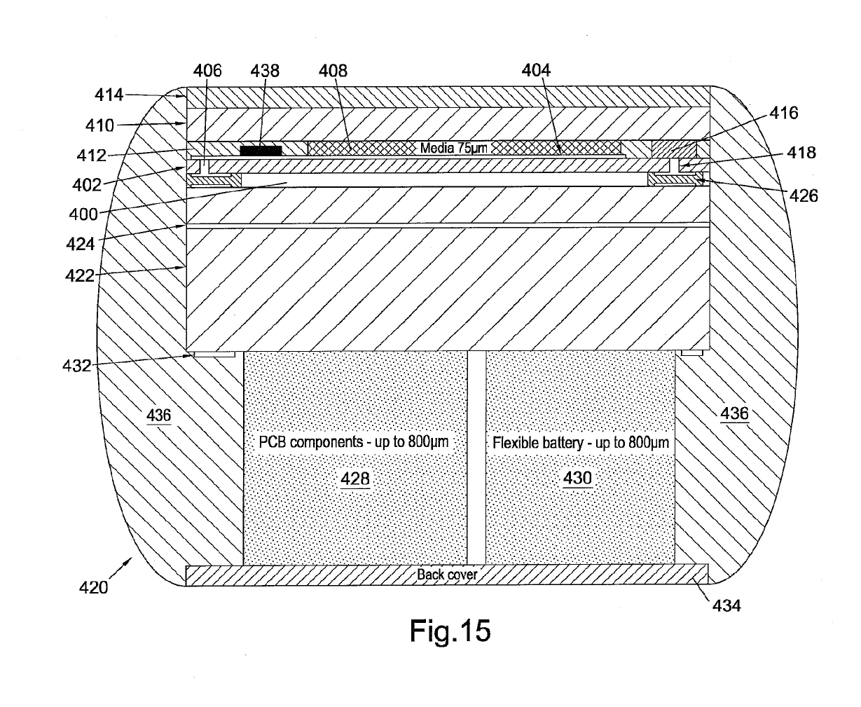

Referring now to FIG. 15, this shows a vertical cross-section view through a display unit of a display embodiment 400 of any option, in which electronic components of the unit are distributed over a surface of the unit on a flexible PCB. Additionally or alternatively such electronic components may be at edges of the tiled display as discussed above.

In more detail, the structure comprises a substrate 402, typically a plastic such as PET (polyethyleneterephthalate) or pen(polyethelenemaphthalene) on which is fabricated a thin layer of organic active matrix pixel circuitry. The circuitry may comprise an array of organic (or inorganic) thin film transistors for example as previously described in our WO001/47045, WO2004/070466, WO01/47043, WO2006/059162, WO2006/056808, WO2006/061658, WO2006/106365 and WO2007/029028. Broadly speaking in embodiments the backplane is fabricated using solution based techniques patterned by, for example, direct-right printing, laser ablation or photolithography to fabricate the thin film transistors. In embodiments the active devices have a thickness of order 5-10 μm. In embodiments this layer has a thickness of order 50 μm and has integrated encapsulation. This substrate/backplane layer bears row and column, dataline and address conductive tracks 404, connected to the rear of substrate 402 by vias 406. We here refer to front as being towards the display surface of the display unit and rear as being towards the rear of the display unit.

A display medium 408 is attached to substrate 402, for example by adhesive. In preferred embodiments the display medium is a reflective display medium (which facilitates daylight reading), for example an electrophoretic display medium or an electrofluidic display medium. Where an electrophoretic display medium is employed a colour display unit may be provided by providing a colour filter array 410 over the display medium; optionally this may also perform an encapsulation function. Additionally or alternatively a moisture barrier may be provided over the display medium, for example comprising polyethylene and/or Aclar™ (a fluropolymer, polychlorotrifluoroethylene-PCTFE). In some embodiments the thickness of the display medium is of order 75 μm and that of the encapsulation/colour filter array of order 120 μm.

Where an electrofluidic display medium is employed, for example of the type available from Gamma Dynamics, Inc. Ohio USA, the colour filter array may be omitted. The use of an electrofluidic display medium facilitates improved brightness/contrast as well as near video display update rates and high resolution, in embodiments of order 225 pixels per inch.

In embodiments whichever display medium is employed, an edge seal 412 is provided to seal the edge of display medium 408 to the edge of the display module.

A front window 414 is provided over the display unit, for example comprising a thin layer of PMMA (polymethylmethacrylate), in embodiments with a thickness of order 75 μm. Where the display unit is touch sensitive, this layer may also include conductive row and column lines for the touch circuitry, in embodiments employing fine line metal (FLM). The touch sensing circuitry may be operable by finger and/or a stylus. A connection to the touch sensing layer may be made by a Z-axis conductive pad 416 which connects to the touch electrodes in window 414 through CFA/encapsulation layer 410 (for example by vias, not shown) and vias 418 through substrate 402 bring the touch array connections to contact pads on the rear of substrate 402.

Similarly as for FIG. 13, an adhesive layer 420 connects the substrate 402 to a flexible PCB 422 (which may incorporate circuitry 424 for an inductive stylus sensor. Connections between the contact pads on the rear of substrate 402 and the flexible PCB employ an isotropic conductive film (ACF) 426. The illustrated structure facilitates the omission of a separate moisture barrier under substrate 402, although such a barrier may be incorporated if desired.

Flexible PCB 422 carries electronic components 428, for example surface mounted components, and a thin film flexible polymer battery 430. In embodiments the PCB 422 has a thickness of order 600 μm, and the components/battery have a thickness up to 800 μm. Flexible PCB 422 also bears a conductive loop 432 around the border of the device for inductive charging of battery 430.

The components and battery are provided with a thin rear cover 434 (optional). The display part and PCB module is encapsulated, for example by a gel-based potting material or encapsulant 436 which, in embodiments, fills all the internal gaps, extending around the edge of the display module, over the flexible PCB, and attaching rear cover 434.

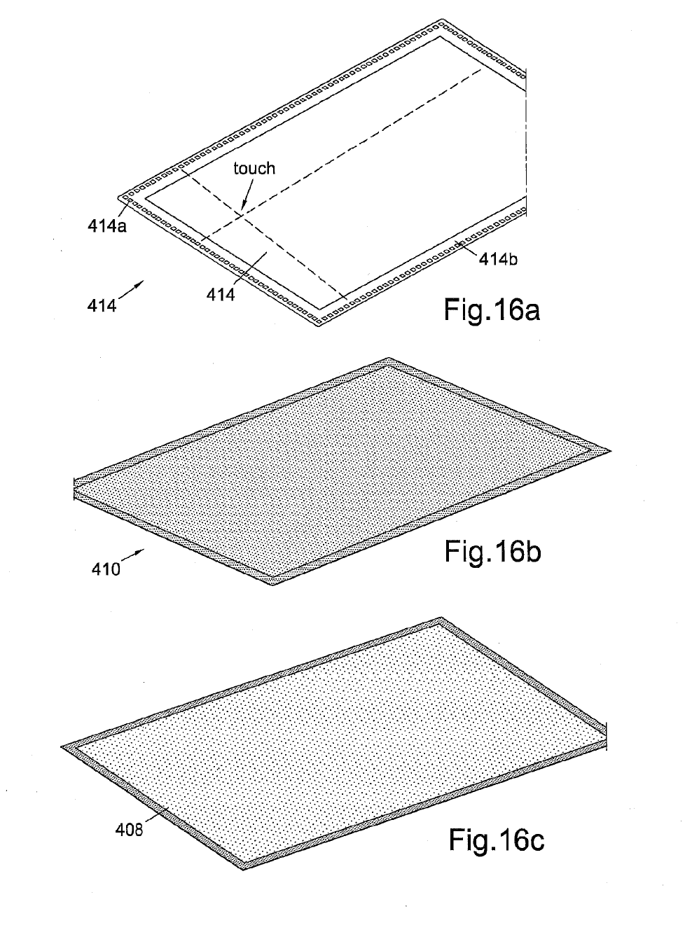

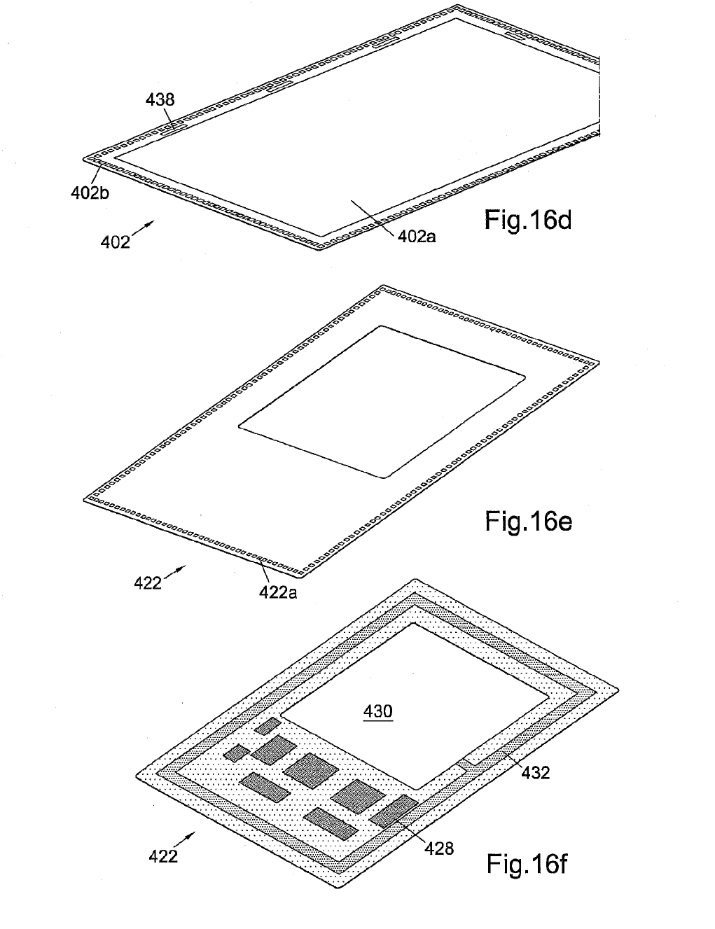

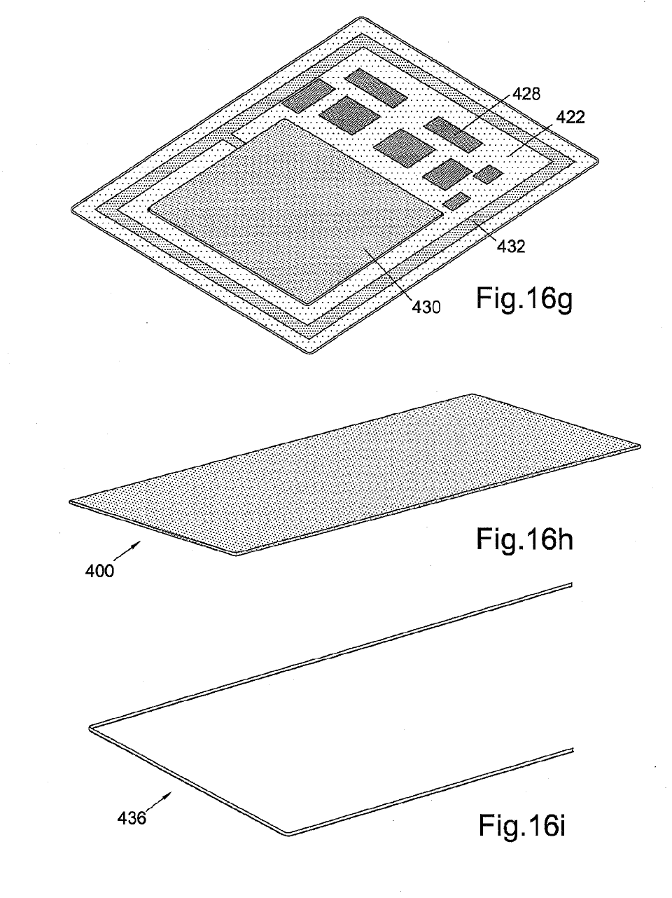

Referring next to FIGS. 16a to 16i, these show perspective views of layers illustrated in the cross-section of FIG. 15, layers such as are shown in FIGS. 13a to 13i further suitable however for use with a structure as shown in FIG. 13. Thus FIG. 13a shows plastic front window 414 which protects the display medium and, where present, the colour filter array. This window has a plurality of pads 414a around the edge which connect to tracks on the touch sensor FLM (fine line metal) in the case of a capacitive sensor. In embodiments the fine line metal has a width in the range 2-5 μm. The window 414 provides a narrow border 414b around the active display area.

FIG. 16b shows a plan view of the colour filter array 410, again with a narrow border. In embodiments this may provide a regular pattern of red, green, blue and white colours.

FIG. 16c shows the display medium 408, with the active area of the media substantially following the entire available area. FIG. 16d shows substrate 402 having an active backplane area 402a for driving pixels of the display medium 408. Substrate 402 is provided with pads 402b around the edge to carry touch signals between the touch electrodes of window 414 and touch sensing circuitry on PCB 422. Substrate 402 may also bear a plurality of display driver integrated circuits 438, mounted on substrate 402 using chip-on-plastic technology; however these may be provided additionally or alternatively at the edge of the tiled display as discussed above. Connections to these when made, for example, are by other pads (not shown).

FIG. 16e shows the front (display-facing) face of optional flexible PCB 422, illustrating pads 422a around the border which connect to the display/touch sensing module via an isotropic conductive film.

FIG. 16f shows, schematically, the rear face of PCB 422, illustrating optional components 428, battery location 430 and inductive loop 432, noting however that any one or more of these may however be provided at the edge of the tiled display.

FIG. 16g is a similar illustration to FIG. 16f showing the flexible battery 430 in an example position. The electronic components 428, which may be mounted on the display unit or at the edge of the tiled display, include, in embodiments a single chip processor, a display engine, and Bluetooth™/near-field communications. As illustrated the battery 430 may be recharged by holding the device over an inductive charging pad, but in alternative approaches a capacitive charge electrode may be employed for capacitive charging.

FIG. 16h shows a rear view of the device 400, illustrating the thinness of the device—in embodiments the device is of order 2 mm thick; where the driver circuitry is provided at the edge of the tiled display however the thickness may be even less, e.g., about 1 mm or less. FIG. 16i shows an edge profile of the display unit formed by encapsulant 436.

No doubt many other effective alternatives will occur to the skilled person. It will be understood that the invention is not limited to the described embodiments and encompasses modifications apparent to those skilled in the art lying within the spirit and scope of the claims appended hereto.

1. Reflective display apparatus having a flexible display panel and driver electronics to drive the flexible display panel, the flexible display panel comprising at least first and second flexible display units, the driver electronics configured to drive said flexible display units to display respective image regions, wherein said first and second said flexible display units are adjacent and each comprise:
a display layer comprising display medium; and
a control layer having a backplane and a substrate to support the backplane, the backplane to control said display layer to display an image region,
wherein:
the driver electronics comprises a first drive electronics unit to control the backplane of said first display unit and a second drive electronics unit to control the backplane of said second display unit, said first drive electronics unit disposed on said first display unit and said second drive electronics unit disposed on said second display unit,
a said drive electronics unit is mounted behind a said substrate of a said adjacent display unit to thereby substantially hide the said drive electronics unit from a user viewing a said image region displayed on the said adjacent display unit, wherein the display layer of the said adjacent display unit is in front of the said substrate, the said drive electronics unit attached to a said adjacent display unit.

2. Reflective display apparatus according to claim 1, wherein:
an edge region of the first display unit has an extension beyond the display layer of the first display unit, said extension attached to said first drive electronics unit; and
the second display unit overlaps said first display unit to thereby substantially hide said first drive electronics unit from a user viewing a said image region displayed on the second adjacent display unit.

3. Reflective display apparatus according to claim 1, wherein the second display unit overlaps said first display unit to thereby substantially hide an edge region of the display layer of the first display unit from a user viewing a said image region displayed on the second adjacent display unit.

4. Reflective display apparatus according to claim 1, wherein:
said first drive electronics unit is attached to a back surface of the first display unit; and
each of said first and second said display units has a region comprising a via through the substrate of the display unit, the via electrically coupled to the backplane of the display unit,
the display apparatus comprising:
a conductive interconnection layer on the back surface of the first display unit and on the back surface of the second display unit, the interconnection layer extending between said vias,
wherein the first or second drive electronics unit is coupled to said conductive interconnection layer.

5. Reflective display apparatus having a flexible display panel and driver electronics to drive the flexible display panel, the flexible display panel comprising at least first and second flexible display units, the driver electronics configured to drive said flexible display units to display respective image regions, wherein said first and second said flexible display units are adjacent and each comprise:
a display layer comprising display medium; and
a control layer having a backplane and a substrate to support the backplane, the backplane to control said display layer to display an image region,
wherein the display apparatus comprises:
an interconnection arranged to electrically couple the first and second flexible display units such that at least one signal to drive the backplane of the first display unit is receivable from the backplane of the second display unit.

6. Reflective display apparatus of claim 5, wherein said interconnection is arranged to physically couple at least one electrode of said first display unit to at least one electrode of the second display unit, wherein said at least one electrode of the first display unit is electrically coupled to the backplane of said first display unit and said at least one electrode of the second display unit is electrically coupled to the backplane of said second display unit.

7. Reflective display apparatus of claim 5, wherein:
the control layer of the first display unit has an extension beyond the display layer of the first display unit, the extension comprising at least one electrode electrically coupled to the backplane of the first display unit; and
said interconnection electrically couples the at least one electrode to the backplane of the second display unit such that the at least one said signal is receivable by the at least one electrode.

8. Reflective display apparatus of claim 5, the backplane of each of said first and second flexible display units comprising a plurality of transistors, control electrodes and source electrodes, wherein:
each said transistor of a said flexible display unit is configured to receive a control signal from a said control electrode and a source signal from a said source electrode and configured to drive a region of the display medium of the flexible display unit by controllably passing said received source signal, said controllable passing under control of said received control signal; and
the at least one electrode of said first display unit comprises a said control electrode and the at least one electrode of said second display unit comprises a said control electrode, the interconnection arranged to electrically couple said control electrodes.

9. Reflective display apparatus of claim 5, the backplane of each of said first and second flexible display units comprising a plurality of transistors, control electrodes and source electrodes, wherein:
each said transistor of a said flexible display unit is configured to receive a control signal from a said control electrode and a source signal from a said source electrode and configured to drive a region of the display medium of the flexible display unit by controllably passing said received source signal, said controllable passing under control of said received control signal; and
the at least one electrode of said first display unit comprises a said source electrode and the at least one electrode of said second display unit comprises a source electrode, the interconnection arranged to electrically couple said sources electrodes.

10. Reflective display apparatus of claim 1, wherein the driver electronics comprises a driver electronics unit located beyond an edge of the display panel.

11. Reflective display apparatus of claim 1, each of the first and second display units lacking driver electronics mounted on the display unit.

12. Reflective display apparatus of claim 7, wherein:
the control layer of the second display unit has an extension beyond the display layer of the second display unit, the extension comprising at least one electrode electrically coupled to the backplane of the second display unit;
the interconnection couples the extensions of the first and second display units at an interface between said adjacent display units, and:
at least one said extension of a said display unit has a curvature toward a non- viewing side of the display unit, said curvature to reduce a gap between the display layers of the adjacent display units at said interface.

13. Reflective display apparatus of claim 12, wherein a said curvature of at least one of said extensions is about 90 degrees such that said coupled extensions extend substantially perpendicular to the display layer of at least one said adjacent display unit.

14. Reflective display apparatus of claim 2, wherein the curvature of at least one of said extensions is such that the display layers of the adjacent display units are directly opposing at said interface.

15. Reflective display apparatus of claim 12, wherein the at least one said extension comprises a track of a said electrode, said curvature such that said electrode track is curved, the extension further comprising polymer such as Pedot over the electrode track.

16. Reflective display apparatus of claim 7, wherein:
the second display unit comprises a via through the substrate of the second display unit; and
the second display unit overlaps the extension of said first display unit such that said via is located over the extension of the first said adjacent display unit,
wherein said interconnection comprises said via.

17. Reflective display apparatus of claim 16, comprising anisotropic conductive film disposed to electrically couple said via to the second display unit.

18. Reflective display apparatus of claim 16, wherein:
the substrate and display layer of the second display unit extend over the extension of the first display unit.

19. Reflective display apparatus of claim 16, wherein the extension of said first display unit comprises a track of a said electrode and polymer such as Pedot over the electrode track.

20. Reflective display apparatus of claim 16, wherein the substrate comprising said via comprises plastic.

21. Reflective display apparatus of claim 1, wherein a gap between said display layers of said adjacent first and second display units has a shortest width less than about 1 mm.

22. Reflective display apparatus of claim 1, wherein at least one of said adjacent display units comprises a planarisation layer disposed on the backplane of the display unit, said planarisation layer for reducing cracking of electrical tracks of the backplane of.

23. Reflective display apparatus of claim 1, wherein the substrate of at least of the adjacent display unit comprise PET or PEN.

24. Reflective display apparatus of claim 1, wherein said display medium comprises electrophoretic, electrowetting, electrofluidic or OLED display medium.

25. Reflective display apparatus of claim 1, the driver electronics configured to drive said flexible display units to display an image comprising said respective image regions.

26. Reflective display apparatus of claim 1, wherein electrical routing between a said backplane of a first said display unit and a drive electronics unit configured to drive said backplane is arranged behind an adjacent said display unit to thereby substantially hide said drive electronics unit from a user viewing an image region displayed on the first display unit.

27. (canceled)

28. Method of forming a flexible display unit for a reflective display apparatus having a flexible display panel and driver electronics to drive the flexible display panel, the flexible display panel comprising at least first and second said flexible display units, the driver electronics configured to drive said flexible display units to display respective image regions, wherein said first and second said flexible display units are adjacent, the display unit having a display layer comprising display medium and having a control layer having a backplane and a substrate to support the backplane, the backplane to control said display layer to display an image region, the method comprising:
processing a process element comprising a said substrate, a said display layer and a said backplane, said element adhered to a substantially rigid plate during said processing, said plate for supporting said unit and reducing deformity of the display layer during said processing;
substantially inhibiting said adherence after said processing;
separating said unit and said plate when said adherence is substantially inhibited; and
depositing an electrically conductive layer on a back surface of said unit, wherein the display layer is visible through a front, display surface of the unit, said depositing when the back surface has been exposed by said separating.

29. Method of claim 28, further comprising mounting on said conductive layer a drive electronics unit of said driver electronics, said mounting preferably comprising using solder or ACF to bond said drive electronics unit to said conductive layer.

30. Method of claim 28, further comprising bonding said conductive layer to an electrode of another said display unit, said bonding preferably using ACF or solder.

31. Method of claim 30, wherein said bonding provides an interconnection that electrically couples the flexible display unit to the another display unit such that at least one signal to drive the backplane of the flexible display unit is receivable from the backplane of the another display unit.

32.-35. (canceled)
